(19) United States
(12) Patent Application Publication
(10) Pub. No.: US 2007/0168799 A1
(43) Pub. Date: Jul. 19, 2007

(54) Dynamically configurable scan chain testing

(76) Inventor: Alessandro Paglieri, Bussana di Sanremo (IT)

Correspondence Address: TEXAS INSTRUMENTS INCORPORATED, P O BOX 655474, M/S 3999, DALLAS, TX, 75265, US

(21) Appl. No.: 11/297,602

(22) Filed: Dec. 8, 2005

(51) Int. Cl. G01R 31/28

(52) U.S. Cl. 714/726

(57) ABSTRACT

An integrated circuit comprises a circuit under test, a plurality of scan chains coupled to the circuit under test, and a dynamically configurable input selection logic. The dynamically configurable input selection logic couples to the scan chains, receives one or more scan input bit streams, and provides a scan input bit stream to any of the scan chains in accordance with a dynamically controllable control signal. In this manner, pins on the integrated circuit may be shared among multiple scan chains and the integrated circuit may be tested in accordance with any of a plurality of selectable scan chain configurations.

### BACKGROUND OF THE INVENTION

1. Technical Field

The present subject matter relates in general to electronic circuits and, more particularly, to an electronic circuit with a dynamically configurable scan path.

2. Background Information

As integrated circuit designs become denser and more complicated, the need for testing increases. Scan path testing, in which test data is provided to various circuit modules and the resultant output is compared to expected results, is a widely used and powerful testing scheme. Unfortunately, scan path testing is one of the larger costs involved in manufacturing an electronic device. Further, it can be difficult to develop a testing scheme for a particular integrated circuit that completely tests the circuit.

### BRIEF SUMMARY

In accordance with at least some embodiments, an integrated circuit comprises a circuit under test, a plurality of scan chains coupled to the circuit under test, and a dynamically configurable input selection logic. The dynamically configurable input selection logic couples to the scan chains, receives one or more scan input bit streams, and provides a scan input bit stream to any of the scan chains in accordance with a dynamically controllable control signal. The integrated circuit also may comprise a dynamically controllable output selection logic that selects various scan chain outputs for combining into a single scan output from the integrated circuit. With this architecture, multiple scan chains can be loaded in parallel in a dynamically flexible manner so as to permit the implementation any of a plurality of test configurations. Further, multiple scan chains may share a single pin on the integrated circuit.

### NOTATION AND NOMENCLATURE

Certain terms are used throughout the following description and claims to refer to particular system components. As one skilled in the art will appreciate, various companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to.” Also, the term “couple” or “couples” is intended to mean either an indirect or direct connection. Thus, if a first device couples to a second device, that connection may be through a direct connection, or through an indirect connection via other devices and connections.

### BRIEF DESCRIPTION OF THE DRAWINGS

For a more detailed description of the preferred embodiments of the present invention, reference will now be made to the accompanying drawings, wherein:

FIG. 1 depicts an integrated circuit comprising a circuit under test and dynamically configurable scan path testing circuitry.

### DETAILED DESCRIPTION OF THE PREFERRED EMBODIMENTS

The following discussion is directed to various embodiments of the invention. Although one or more of these embodiments may be preferred, the embodiments disclosed should not be interpreted, or otherwise used, as limiting the scope of the disclosure, including the claims, unless otherwise specified. In addition, one skilled in the art will understand that the following description has broad application, and the discussion of any embodiment is meant only to be exemplary of that embodiment, and not intended to intimate that the scope of the disclosure, including the claims, is limited to that embodiment.

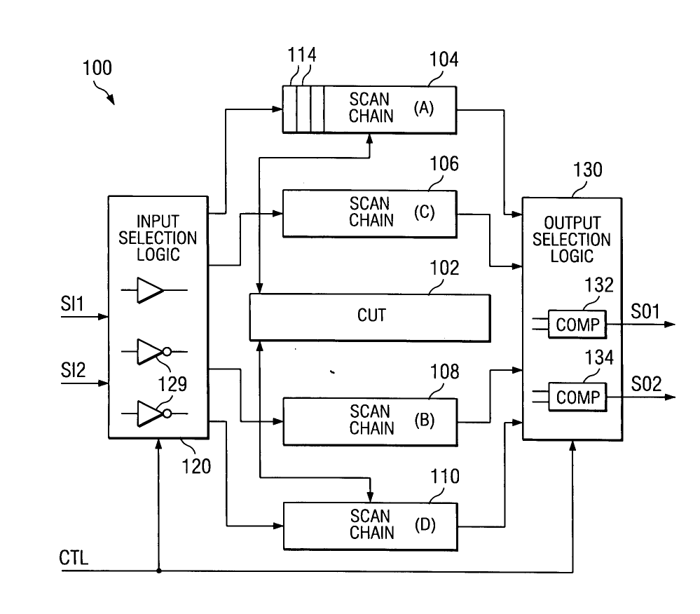

FIG. 1 depicts an integrated circuit (“IC”) 100 in accordance with a preferred embodiment of the invention. As shown, the IC comprises a circuit under test (“CUT”) 102 which may include some or all of the functional circuitry of the IC. In general, IC 100 comprises sequential elements and combinatorial logic and the CUT 102 comprises the IC's combinatorial logic. The IC 100 may be any desired IC to be tested such as, without limitation a digital signal processor. As the name implies, the circuit under test 102 is the combinatorial logic of IC 100 that is being tested in accordance with the preferred embodiments discussed herein.

The IC 100 of FIG. 1 also includes one or more scan chains 104, 106, 108, and 110. Each scan chain preferably comprises one or more sequential elements (e.g., shift registers 114) as is commonly known. Each scan chain 104-110 may comprise a complete scan chain or a segment of a longer scan chain. The shift registers 114 of the scan chains 104-110 couple to the CUT 102. Test data may be provided through the scan inputs (SI1 and SI2), through input selection logic 120, through the scan chains 104-106 and to the CUT 102. Outputs from the CUT 102 are provided via the scan chains to the output selection logic 130 and out of the IC 100 via the scan outputs (SO1 and SO2). Each scan input SI1, SI2 is provided to the IC 100 via a pin (not specifically shown) on the IC. As such, the IC 100 requires two pins for the scan inputs in the example of FIG. 1. Similarly, the IC 100 provides two output pins (not specifically shown) for accessing the scan outputs SO1 and SO2.

The scan chain testing scheme depicted in FIG. 1 permits multiple scan chains to be loaded in parallel in any of a plurality of dynamically controllable configurations. The SI1 test input bit stream may be provided to any two of the scan chains 104-110 shown in FIG. 1. The SI2 test input bit stream may be provided to the other two scan chains (and thus also to any two scan chains). For example, the SI1 bit stream may be provided to scan chains 104 and 106, while the SI2 bit stream may be provided to scan chains 108 and 110. Continuing this example, the data loaded into scan chains 104 and 106 would be the same, but different than the data loaded into scan chains 108 and 110. Once the data is operated on by the CUT 102, the output from the scan chains is provided in parallel to the output selection logic 130 which comprises two compression circuits 132 and 134. Each compression circuit combines two bit streams from two of the scan chains into a single output bit stream. Compression circuit 132 thus combines two bit streams from scan chains 104-110 into a single output bit stream SO1. Similarly, compression circuit 134 combines the other two bit streams from the scan chains into a single output bit stream SO2. In this way, four scan chains 104-110 can be used to test the CUT 102 while only requiring two scan input pins and two scan output pins. The compression circuits 132 and 134 may comprise any suitable circuits such as exclusive OR logic gates. The scan outputs SO1 and SO2 are then compared to predicted patterns to determine whether an error occurred during testing.

The input selection logic 120 shown in FIG. 1 permits the dynamic implementation of any of a plurality of test configurations. In this context, “dynamic” refers to implementing a test configuration for the integrated circuit after the integrated circuit has been fabricated and being able to change the test configuration as desired. The input selection logic 120 permits either input SI1 and SI2 to be provided to any of the four outputs 121, 123, 125, or 127 from the selection logic. Thus, the input selection logic permits each input SI1 or Si2 to be provided to any of the scan chains and to any pair of scan chains. Further, the input selection logic 120 comprises one or more dynamically selectable inverters 129 that can be used to logically invert either or both of the input bit streams SI1 or SI2. The control as to which scan inputs are provided which scan chains and whether inverters are to be used or not is dictated by the control signal (“CTL”). The CTL control signal may be generated internally to the IC 100 by a suitable test interface (e.g., JTAG). Alternatively, the CTL control signal may be generated external to the IC and provided to the input selection logic 120 via a pin on the IC.

The CTL control signal also configures the output selection logic 130 to provide any pair of the scan chain outputs to either compression circuit 132, 134. As such, if the input selection logic 120 is configured to provide the SI1 input bit stream to scan chains 106 and 108, then the output selection logic 130 may be configured to provide the outputs from scan chains 106 and 108 to the same compression circuit which may be either compression circuit 132 or 134.

With the dynamically configurable architecture described above and illustrated in FIG. 1, a plurality of test configurations are possible. Being able to test the CUT 102 with a plurality of different configurations helps to ensure that a more complete test is performed on the CUT 102. Referring still to FIG. 1, the scan chains 104-110 may be loaded with test data A, C, B, and D, respectively, as referenced in parentheses in the scan chains. The dynamically selectable nature of the input selection logic 120 and output selection logic 130 as well as the selectable inverters in the input selection logic 120 permits any of the exemplary configurations shown in Table I to be implemented during a test.

TABLE I
Exemplary Configurations

(A = C) ≠ (B = D)
(A = −C) ≠ (B = −D)
(A = B) ≠ (C = D)
(A = −B) ≠ (C = −D)

The embodiments described herein enable a reduction in test time, compared to conventional scan chain testing schemes, in that multiple scan chains can be loaded and processed in parallel. Further, by loading multiple scan chains with the same test vectors, test data volume is reduced compared to conventional testing schemes.

While the preferred embodiments of the present invention have been shown and described, modifications thereof can be made by one skilled in the art without departing from the spirit and teachings of the invention. The embodiments described herein are exemplary only, and are not intended to be limiting. Many variations and modifications of the invention disclosed herein are possible and are within the scope of the invention. For instance, any number of scan chains may be implemented. Further, although a scan input bit stream is described as being provided to two scan chains in parallel, in other embodiments a scan input bit stream may be provided to only a single chan chain or more than two scan chains if desired. The single particular scan chain receiving the scan input bit stream is dictated by the dynamically controllable control signal. Accordingly, the scope of protection is not limited by the description set out above. Each and every claim is incorporated into the specification as an embodiment of the present invention.

What is claimed is:

1. An integrated circuit, comprising:
a circuit under test;
a plurality of scan chains coupled to the circuit under test; and
a dynamically configurable input selection logic that is coupled to the scan chains, receives one or more scan input bit streams, and provides a scan input bit stream to any of the scan chains in accordance with a dynamically controllable control signal.

2. The integrated circuit of claim 1 further comprising a dynamically configurable output selection logic that is coupled to the scan chains, receives two or more output bit streams from said scan chains, and compresses said two or more output bit streams into a single scan output bit stream, wherein the two or more output bit streams are selected from scan chains dictated by the dynamically controllable control signal.

3. The integrated circuit of claim 1 wherein the dynamically configurable input selection logic provides a common scan input bit stream to a pair of scan chains in accordance with the dynamically controllable control signal.

4. The integrated circuit of claim 1 wherein the dynamically configurable input selection logic comprises a selectable inverter that permits a scan input bit stream to be logically inverted and thus an inverted form of a scan input bit stream to be provided to a scan chain.

5. An integrated circuit, comprising:
a circuit under test;
a plurality of scan chains coupled to the circuit under test; and
means for receiving one or more scan input bit streams and for providing a scan input bit stream to any of the scan chains in accordance with a dynamically controllable control signal.

6. The integrated circuit of claim 5 further comprising means for selecting two or more output bit streams from said scan chains and for compressing said two or more selected output bit streams into a single scan output bit stream.

7. The integrated circuit of claim 5 wherein said means for providing a scan input bit stream to any of the scan chains comprises means for providing a common scan input bit stream to a pair of scan chains in accordance with the dynamically controllable control signal.

8. The integrated circuit of claim 5 wherein said means for providing a scan input bit stream to any of the scan chains comprises means for inverting a scan input bit stream.

9. The integrated circuit of claim 5 wherein said means for providing a scan input bit stream to any of the scan chains comprises means for providing a plurality of logically inverted scan input bit streams to two or more of the scan chains.

10. A method, comprising:
asserting a control signal to an input selection logic associated with an integrated circuit to cause the input selection logic to provide a common scan input test bit stream to any of a plurality of scan chains dictated by the control signal.

11. The method of claim 10 further comprising combining outputs from a plurality of scan chains as dictated by the control signal.

12. The method of claim 10 wherein asserting a control signal comprises asserting a control signal to cause the input selection logic to provide a common scan input test bit stream to any two of a plurality of scan chains as dictated by the control signal.

13. The method of claim 10 wherein asserting a control signal comprises asserting a control signal to cause the input selection logic to provide a first scan input test bit stream to any two of a plurality of scan chains as dictated by the control signal and to provide a second scan input test bit stream to any two of a plurality of other scan chains as dictated by the control signal.

14. The method of claim 10 wherein asserting a control signal also comprises asserting a control signal to cause the input selection logic to logically invert a scan input test bit stream to a scan chain.
